(19) United States
(12) Patent Application Publication
(10) Pub. No.: US 2012/0086010 A1
(43) Pub. Date: Apr. 12, 2012

(54) ELECTRONIC IMAGE DETECTION DEVICE

(75) Inventors: Benoît Giffard, Grenoble (FR); Yvon Cazaux, Grenoble (FR)

(73) Assignee: Commissariat a l'Energie Atomique et Aux Energies, Paris (FR)

(21) Appl. No.: 13/259,369

(22) PCT Filed: Apr. 1, 2010
(86) PCT No.: PCT/FR2010/050629

§ 371 Date: Dec. 13, 2011

(30) Foreign Application Priority Data
Apr. 2, 2009 (FR) 0952111

(51) Int. Cl. H01L 31/0376

(52) U.S. Cl. 257/59; 257/E31.048

(57) ABSTRACT

The instant disclosure relates to an electronic image detection device comprising: a plurality of metal electrodes on a first face of an insulating layer; and amorphous silicon regions extending over the insulating layer between the metal electrodes.

### FIELD OF THE INVENTION

The present invention relates to an electronic image detection device.

### DISCUSSION OF PRIOR ART

To perform an image detection, it is known to use the CMOS technology and to form, in a semiconductor substrate, pixels comprising photodiodes associated with transistors, for example, precharge and read transistors. Incident photons generate electron/hole pairs and the electrons of these pairs are collected by the photodiodes. The electrons are then converted into a voltage within the pixel before being read by means of an electronic read circuit located at the periphery of a pixel array.

In the case of image sensors intended for night vision or low lighting, it is known, instead of performing the detection on an optical image, to do it on an associated electronic image. To achieve this, the optical image is transformed into an electronic image by a photon-to-electron converter, also called photocathode, which delivers an electron beam array. To increase the general sensitivity of the sensor, an electron amplifier which delivers an amplified electronic image to an electronic image detection device may be provided at the photocathode output.

FIG. 1 is a simplified perspective view of an electronic image detection device.

An insulating layer 12 extends on a support 10. Support 10 is for example formed of a semiconductor substrate comprising active devices (transistors and diodes) of a CMOS integrated circuit on which is formed a stack of interconnection levels interconnecting these active devices. Insulating layer 12 may be a portion of the last level of the interconnection stack. Metal electrodes 14 which are arranged, in the shown example, in an array, extend on insulating layer 12. Each electrode 14 is connected to an element of the integrated circuit formed in the semiconductor substrate by tracks and vias provided in the stack of interconnection levels (not shown). Electrons reaching the surface of the device of FIG. 1 are captured by metal electrodes 14 and then transferred to the integrated circuit for the processing and reading. Thus, in addition to the elements conventionally provided in the pixel, each pixel of the electronic image detection device comprises a metal electrode 14 and metal tracks and vias of connection to the integrated circuit.

When electrons reach portions of insulating layer 12 unprotected by a metal electrode 14, they generate, in the insulator, a trapped electric charge which may influence the quality of the image and, possibly, cause electric breakdowns. The charges stored in the insulating material form an electric field which may deviate incident electrons, thus causing an artifact in the image. To avoid for electrons to reach dielectric material 12, it has been provided to etch the dielectric material around metal electrodes 14 and to thus expose, at the bottom of the etched locations, a metal layer. This metal layer forms a barrier against the penetration of electrons into insulating material 12 and is electrically connected to the CMOS circuit, which enables to drain off the collected electronic charges. A structure in which metal electrodes 14 are below an upper metal protection layer may also be provided.

A staged structure such as discussed hereabove raises two issues. The first one is the fact that the obtained structure has an upper surface which is not planar. This forbids or makes very difficult any subsequent manufacturing process, for example, of forming of connection pads providing contacts on the substrate. Further, electrons may reflect on lower metal portions and reach the insulating material of layer 12, from the stepped side of the structure. Thus, electrons may generate a trapped electric charge in this insulating layer and still result in electric breakdowns and in artifacts in the image.

There thus is a need for an electronic image detection device having a planar upper surface and avoiding the trapping of electrons and the degradation of the dielectric material present under and/or between the metal electrodes.

### SUMMARY

An object of an embodiment of the present invention is to provide an electronic image detection device where the insulating material between the metal electrodes of the pixels is protected from incident electrons.

Another object of an embodiment of the present invention is to provide an electronic image detection device capable of having an upper surface which is more planar than that of prior art image detection devices.

Thus, an embodiment of the present invention provides an electronic image detection device, comprising a plurality of metal electrodes on a first surface of an insulating layer and amorphous silicon regions extending on the insulating layer between the metal electrodes.

According to an embodiment of the present invention, the amorphous silicon is hydrogenated.

According to an embodiment of the present invention, the amorphous silicon is quasi intrinsic.

According to an embodiment of the present invention, trenches are formed in the insulating layer between the metal electrodes.

According to an embodiment of the present invention, at least one gate electrode is provided on a second surface of the insulating layer, in front of at least one amorphous silicon region, said at least one gate electrode being capable of being connected to a bias voltage source.

According to an embodiment of the present invention, the gate electrode extends partially in front of the metal electrodes.

According to an embodiment of the present invention, the amorphous silicon has a thickness ranging between 2 and 500 nm, preferably between 10 and 100 nm.

According to an embodiment of the present invention, the metal electrodes are separated by a distance of approximately 1 μm.

According to an embodiment of the present invention, the metal electrodes are made of aluminum.

According to an embodiment of the present invention, the insulating layer is in contact, on the side of its second surface, with a support formed of a stack of interconnection levels extending on a semiconductor substrate.

According to an embodiment of the present invention, the metal electrodes are connected by conductive vias, formed in the interconnection stack, to electronic components formed in the semiconductor substrate.

An embodiment of the present invention further provides an image sensor comprising a photocathode, a microchannel plate, and an electronic image detection device such as hereabove.

### BRIEF DESCRIPTION OF THE DRAWINGS

The foregoing and other objects, features, and advantages of the present invention will be discussed in detail in the following non-limiting description of specific embodiments in connection with the accompanying drawings:

FIG. 1, previously described, is a simplified perspective view of a conventional electronic image detection device;

FIG. 2 is a cross-section view of an electronic image detection device according to an embodiment of the present invention;

FIG. 3 is a perspective view of an electronic image detection device according to an embodiment of the present invention;

FIG. 4 is a perspective view of an electronic image detection device according to a variation of an embodiment of the present invention;

FIG. 5 is a cross-section view of an electronic image detection device according to a variation of an embodiment of the present invention;

FIG. 6 is a cross-section view of an electronic image detection device according to another variation of an embodiment of the present invention;

FIG. 7 is a cross-section view of an electronic image detection device according to another variation of an embodiment of the present invention;

FIG. 8 is a cross-section view partially illustrating an example of a connection between the elements of a detection device according to an embodiment of the present invention and elements formed in a lower semiconductor substrate; and

FIG. 9 is a block diagram illustrating an image sensor assembly comprising an electronic image detection device.

For clarity, the same elements have been designated with the same reference numerals in the different drawings and, further, as usual in the representation of integrated circuits, the various drawings are not to scale.

### DETAILED DESCRIPTION

FIGS. 2 and 3 are respective cross-section and perspective views of an embodiment of an electronic image detection device.

The detection device is formed on a support 20 formed of a stack of interconnection levels extending on a semiconductor substrate. Electronic components enabling to process the detected electronic image are formed in the substrate and are connected to the detection device by conductive tracks and vias formed in the interconnection stack.

An insulating layer 22 extends on support 20 and metal electrodes 24 are formed at the surface of insulating layer 22. Each metal electrode 24 corresponds to a pixel of the detection device. Insulating layer 22 and metal electrodes 24 may be formed in the same way as the lower interconnection levels and thus form the last level of the interconnection stack of support 20. As an example, insulating layer 22 may be made of silicon oxide and metal electrodes 24 may be made of aluminum. Also as an example, metal electrodes 24 may be distributed in an array at the surface of insulating layer 22.

According to an embodiment, regions 26 formed of amorphous silicon extend, on insulating layer 22, between two adjacent metal electrodes 24. Regions 26 cover the entire surface of the insulating layer which is not covered by metal electrodes 24 to protect the apparent portions of insulating layer 22 from incident electrons. In top view, regions 26 join to surround each electrode 24. Regions 26 reach electrodes 24 and may extend on the walls and on the edges of metal electrodes 24 by thus forming squares around the electrodes.

The amorphous silicon is preferably in the quasi-intrinsic state, to be heavily insulating and have a volume resistivity greater than 10⁹ Ωcm at ambient temperature. Thus, the leakage resistance between two electrodes of two neighboring pixels is very high. Amorphous silicon being a semiconductor, it however allows the transfer of electrons reaching an amorphous silicon region 26 towards the closest metal electrode 24. The signal collected between electrodes 24 thus contributes to the useful signal detected by the pixels.

Preferably, the amorphous silicon is hydrogenated to have a volume resistivity greater than that of simple amorphous silicon, on the order of 10¹⁰ Ω.cm. It may be formed at low temperatures, typically lower than 400° C., which are compatible with the presence of finished electronic components in the lower semiconductor substrate (no degradation of these components).

Hydrogenated amorphous silicon has a natural tendency to be slightly of type N. To avoid for this property to influence the insulating character of silicon regions 26 and to control the conductivity of the amorphous silicon layer, the device of FIG. 2 may comprise a gate electrode 28 formed at the junction between support 20 and insulating layer 22. Electrode 28 extends in front of the regions located between electrodes and, preferably, on a surface slightly larger than the inter-electrode interval (that is, slightly facing metal electrodes 24). Electrode 28 is connected to a bias voltage source V_{G} which enables, due to the metal/insulator/semiconductor stack (28/22/26), to deplete hydrogenated amorphous silicon regions 26. The appearing of a conduction channel in the semiconductor, which would cause too much electric charge flow between two adjacent metal electrodes 24, is thus avoided. It should be noted that electrode 28 may be formed at the same time as conductive tracks present in the penultimate interconnection level of the interconnection stack.

As an example of numerical values, hydrogenated amorphous silicon 26 may have a thickness ranging between 2 and 500 nm, preferably between 10 and 100 nm, and metal electrodes 24 may be separated by a distance on the order of 1 μm.

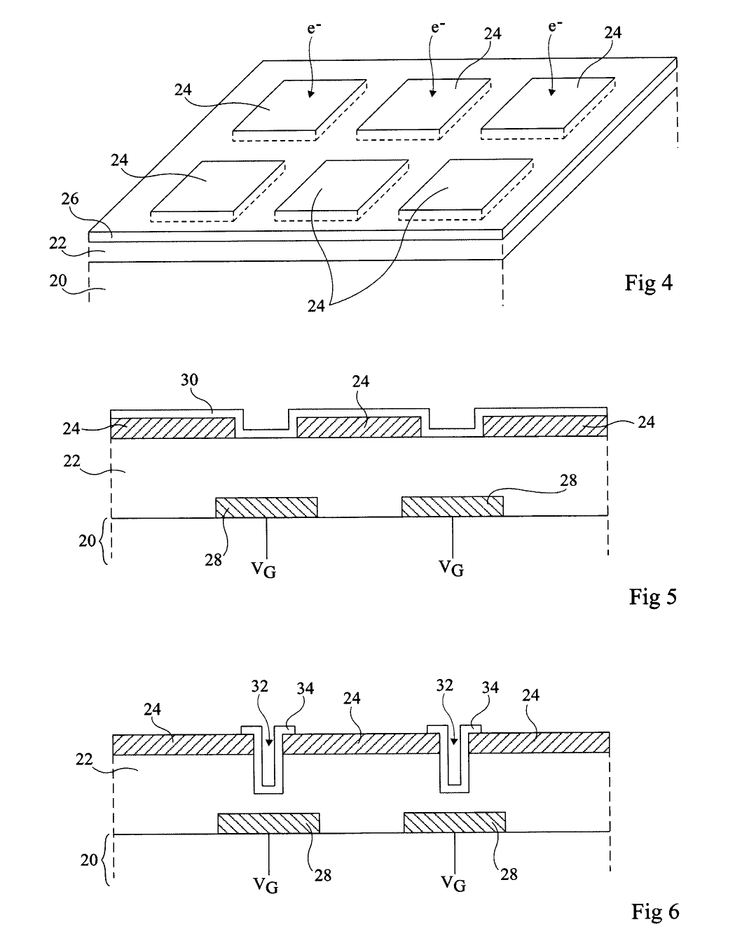

FIG. 4 is a perspective view of an alternative embodiment in which amorphous silicon layer 26 extends around electrodes 24 and has a thickness on the same order as that of electrodes 24. Thus, the obtained structure is planar or quasi planar.

FIG. 5 illustrates an alternative embodiment in which amorphous silicon regions 26 are replaced with an amorphous silicon layer 30 which extends on insulating layer 22 and on electrodes 24. Thus, in top view, amorphous silicon 30 forms a layer having no opening on the electrode array. The electrons reaching amorphous silicon layer 30 are transported by said layer towards underlying metal electrodes 24, amorphous silicon 30 advantageously ensuring the insulation between two neighboring metal electrodes 24. A gate electrode 28, formed at the junction between support 20 and insulating layer 22 and connected to a bias voltage source V_{G}, may assist this insulation, as described hereabove.

FIG. 6 illustrates another alternative embodiment. To insulate two adjacent electrodes 24, areas 32 of insulating layer 22, between electrodes 24, are etched. Amorphous silicon regions 34 extend between metal electrodes 24 by following etched area 32. In this variation, metal electrodes 24 are capable of being closer to one another than in the previously-described variations, the insulation with air in etched areas 32 enabling to avoid interferences between two neighboring electrodes 24.

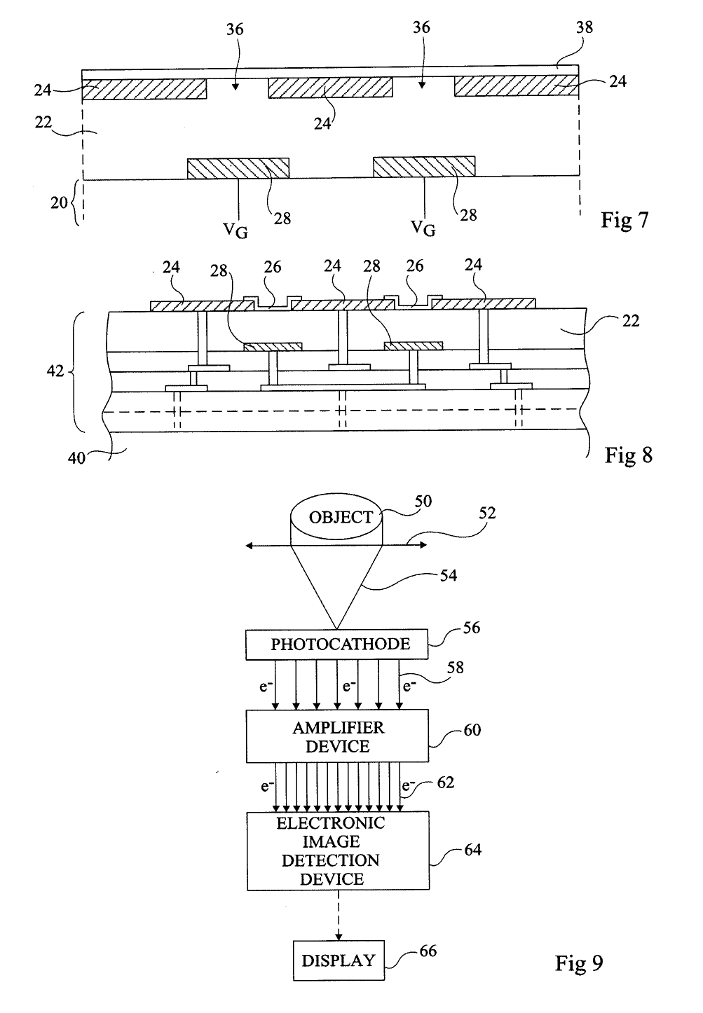

FIG. 7 illustrates another alternative embodiment in which the upper surface of the device is planar. To achieve this, the inter-electrode interval is filled with insulating regions 36, for example, made of a material identical to that of layer 22. An amorphous silicon layer 38 is uniformly deposited over the entire planar surface thus obtained. In the same way as in the variation of FIG. 5, the electrons reaching amorphous silicon layer 38 are transported by said layer towards metal electrodes 24, amorphous silicon 38 also ensuring the insulation between two neighboring metal electrodes 24.

It should be noted that the variations of FIGS. 2-3, 4, and 6 will be preferred to the variations of FIGS. 5 and 7 due to their stability along time. In these two variations, the amorphous silicon does not cover the entire device but is only present between adjacent electrodes, above insulating layer 22, to protect the insulating layer from incident photons. Indeed, the presence of amorphous silicon layer 30, 38 above metal electrodes 24, although it does not influence the detection of electrons from the upper surface of the device, may cause the building up of a few electrons above the electrodes, and thus the forming of a fluctuating charge in the amorphous silicon layer, which may have an impact on the quality of the obtained image. Further, in the case where a flow of incident photons is present, a parasitic electric current may be generated on electrodes 24 due to the photogenerating behavior of amorphous silicon.

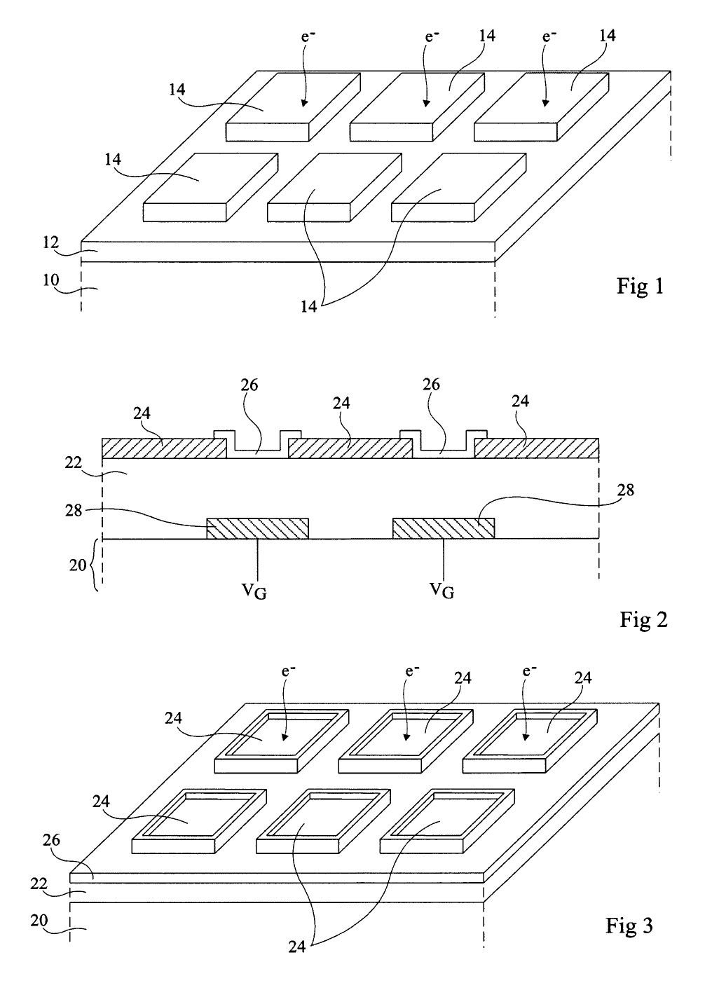

To obtain the structures of FIGS. 2 and 3, the following successive steps may for example be carried out: forming, on a structure such as that in FIG. 1, a continuous amorphous silicon layer by vacuum plasma deposition of silane, at a temperature lower than 200° C.; performing a lithography, by means of an adapted mask, of the formed amorphous silicon layer; and etching the amorphous silicon layer to expose metal electrodes 24, at least in their central regions. To obtain the structure of FIG. 6, insulating layer 22 will be previously etched at the level of the desired amorphous silicon regions.

To obtain the structure of FIG. 4, the following successive steps may for example be carried out: forming, on a structure such as that in FIG. 1, a continuous amorphous silicon layer by vacuum plasma deposition of silane, at a temperature lower than 200° C.; performing a selective chem.-mech. polishing of the amorphous silicon layer over the metal electrodes to expose the upper surface of metal electrodes 24. Thus, the obtained amorphous silicon layer may have a thickness substantially equal to that of metal electrodes 24 or slightly lower than that of metal electrodes 24.

FIG. 8 is a cross-section view partially illustrating an example of possible connections between the electronic image detection device of FIGS. 2 and 3 and elements formed in a lower semiconductor substrate.

In FIG. 8, support 20 is shown in further detail. The support comprises a silicon substrate 40 having a stack of interconnection levels 42 formed at its surface, insulating layer 22 and electrodes 24 forming the last level thereof. Each interconnection level comprises metal tracks which may be interconnected by metal vias. In the shown example, each metal electrode 24 is connected to components formed in substrate 40 (not shown) via vias and metal tracks of stack 42, and gate electrodes 28 are interconnected, also via tracks and vias of stack 42. It should be noted that the gate electrode may be formed of a single metal region and be connected, by a single connection, to bias voltage source V_{G}.

FIG. 9 illustrates, in the form of blocks, an image sensor assembly comprising an electronic image detection device.

The image sensor assembly is intended to form the image of an object 50. Photonic image 54 of object 50, obtained via an optical device 52 for example comprising a lens, is transformed by a photocathode 56 into an electronic image 58. This electronic image is transmitted to an amplifier device 60, for example, a microchannel plate (MCP). Amplified image 62 provided by amplifier device 60 is detected by an electronic image detection device 64 such as discussed herein. Optionally, a display 66 may be provided to display the image detected by electronic image detection device 64.

Specific embodiments of the present invention have been described. Various alterations and modifications will occur to those skilled in the art. In particular, it should be noted that the numerical applications given herein have been indicated as an example only. Further, the electronic image detection device discussed herein may be used in any system requiring the detection of an electronic image, different from that discussed in relation with FIG. 9. Further, in relation with each of the variations of FIGS. 2 to 7, it has been specified that the amorphous silicon regions located between electrodes 24 enable to collect incident electrons, and then to transport them to adjacent electrodes. It should be noted that conductive tracks and vias enabling to drain off the collected electrons, for example, towards a lower substrate, may also be provided in the insulating layer underlying these regions.

1. An electronic image detection device, comprising:
a plurality of metal electrodes on a first surface of an insulating layer; and
amorphous silicon regions extending on the insulating layer between the metal electrodes, and not on the main portion of said metal electrodes.

2. The device of claim 1, wherein the amorphous silicon is hydrogenated.

3. The device of claim 1, wherein the amorphous silicon has a volume resistivity greater than 10⁹ Ω.cm.

4. The device of claim 1, wherein trenches are formed in the insulating layer between the metal electrodes.

5. The device of claim 1, wherein at least one gate electrode is provided on a second surface of the insulating layer, in front of at least one amorphous silicon region, said at least one gate electrode being capable of being connected to a bias voltage source.

6. The device of claim 5, wherein the gate electrode extends partially in front of the metal electrodes.

7. The device of claim 1, wherein the amorphous silicon has a thickness ranging between 2 and 500 nm, preferably between 10 and 100 nm.

8. The device of claim 1, wherein the metal electrodes are separated by a distance of approximately 1 μm.

9. The device of claim 1, wherein the metal electrodes are made of aluminum.

10. The device of claim 1, wherein the insulating layer is in contact, on the side of its second surface, with a support formed of a stack of interconnection levels extending on a semiconductor substrate.

11. The device of claim 10, wherein the metal electrodes are connected by conductive vias, formed in the interconnection stack, to electronic components formed in the semiconductor substrate.

12. An image sensor comprising a photocathode, a microchannel plate, and the electronic image detection device of claim 1.
